(19) United States
(12) Patent Application Publication
(10) Pub. No.: US 2015/0293042 A1
(43) Pub. Date: Oct. 15, 2015

(54) Measurement Device and Measurement Method

(71) Applicant: Semiconductor Energy Laboratory Co., Ltd., Kanagawa-ken (JP)

(72) Inventors: Yasuharu Hosaka, Tochigi (JP); Toshimitsu Obonai, Tochigi (JP)

(73) Assignee: Semiconductor Energy Laboratory Co., Ltd., Kanagawa-ken (JP)

(21) Appl. No.: 14/680,545

(22) Filed: Apr. 7, 2015

(30) Foreign Application Priority Data
Apr. 11, 2014 (JP) 2014-081997

(51) Int. Cl. G01N 27/02; G01R 27/14

(52) U.S. Cl. CPC G01N 27/021; G01R 27/14

(57) ABSTRACT

A measurement method or a measurement device for identifying a factor of a change in the electrical characteristics of a substance is provided. The measurement device includes a chamber, a stage, a stage heating mechanism, a pressure adjusting mechanism, a temperature measuring mechanism, a gas analyzing mechanism, and a probe supporting mechanism. The stage is provided in the chamber and has a function of holding a measured object. The stage heating mechanism has a function of heating the stage. The pressure adjusting mechanism has a function of reducing pressure in the chamber. The temperature measuring mechanism has a function of measuring temperature of the measured object. The gas analyzing mechanism has a function of sensing an element in the chamber. The probe supporting mechanism has functions of supporting a probe and making the probe to be in contact with the measured object.

### BACKGROUND OF THE INVENTION

1. Field of the Invention

One embodiment of the present invention relates to a device for measuring the electrical characteristics of a substance or a device for measuring the thermal characteristics of a substance. One embodiment of the present invention particularly relates to a device for measuring both the thermal characteristics and the electrical characteristics of a thin film

One embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a measurement device, an analysis device, a semiconductor device, a display device, a light-emitting device, a lighting device, a power storage device, a memory device, a method for driving any of them, and a method for manufacturing any of them.

2. Description of the Related Art

A technique in which a transistor is formed using a semiconductor material has attracted attention. The transistor is applied to a wide range of electronic devices such as an integrated circuit (IC) or an image display device (also simply referred to as a display device). As semiconductor materials applicable to the transistor, silicon-based semiconductor materials have been widely used, but oxide semiconductors have been attracting attention as alternative materials.

For example, a technique for forming a transistor using zinc oxide or an In—Ga—Zn-based oxide semiconductor as an oxide semiconductor is disclosed (see Patent Documents 1 and 2).

Note that the physical properties of thin films included in a semiconductor element such as a transistor and thin films around the semiconductor element affect the electrical characteristics and the reliability of the semiconductor element. For this reason, many analysis methods, evaluation methods, and the like of a thin film have been considered.

### REFERENCE

### Patent Documents

[Patent Document 1] Japanese Published Patent Application No. 2007-123861

[Patent Document 2] Japanese Published Patent Application No. 2007-096055

### SUMMARY OF THE INVENTION

It is known that the electrical characteristics of a substance such as a semiconductor, an insulator, or a conductor depend on temperature. However, the electrical characteristics of a substance are changed not only by external factors such as temperature but also by a variety of internal factors. Thus, an intrinsic factor of the change in the electrical characteristics of a substance cannot be accurately identified only by measuring the electrical characteristics while temperature is simply changed.

The internal factors of the change in the electrical characteristics of a substance are, for example, adsorption of molecules or atoms on a surface of the substance, a chemical reaction on the surface of the substance or inside the substance, diffusion of molecules or atoms into the substance, and release of elements contained in the substance to the outside.

The electrical characteristics are significantly changed particularly when elements contained in the substance are released to the outside and the composition of the substance is thus changed. In the case of an oxide, for example, oxygen is released at high temperatures; thus, the electrical characteristics of the oxide are greatly changed. In the case of a material containing a low-melting-point metal, part of the low-melting-point metal might sublime at high temperatures; thus, the conductivity of the material might be changed.

An object of one embodiment of the present invention is to provide a measurement method or a measurement device for identifying a factor of a change in the electrical characteristics of a substance. Another object is to provide a measurement method or a measurement device for determining the temperature dependence of the electrical characteristics of a substance. Another object is to provide a measurement method or a measurement device for measuring a change in the electrical characteristics due to a change in the composition of a substance.

Another object of one embodiment of the present invention is to provide a novel measurement method. Another object is to provide a novel measurement device.

Note that the descriptions of these objects do not preclude the existence of other objects. In one embodiment of the present invention, there is no need to achieve all the objects. Other objects will be apparent from and can be derived from the descriptions of the specification and the like.

One embodiment of the present invention is a measurement device including a chamber, a stage, a stage heating mechanism, a pressure adjusting mechanism, a temperature measuring mechanism, a gas analyzing mechanism, and a probe supporting mechanism. The stage is provided in the chamber and has a function of holding a measured object. The stage heating mechanism has a function of heating the stage. The pressure adjusting mechanism has a function of reducing pressure in the chamber. The temperature measuring mechanism has a function of measuring temperature of the measured object. The gas analyzing mechanism has a function of sensing an element in the chamber. The probe supporting mechanism has functions of supporting a probe and making the probe to be in contact with the measured object.

Another embodiment of the present invention is a measurement device including a chamber, a stage, a first mechanism, a second mechanism, a third mechanism, a fourth mechanism, and a fifth mechanism. The stage is provided in the chamber and has a function of holding a measured object. The first mechanism has a function of heating the stage. The second mechanism has a function of reducing pressure in the chamber. The third mechanism has a function of measuring temperature of the measured object. The fourth mechanism has a function of sensing an element in the chamber. The fifth mechanism has functions of supporting a probe and making the probe to be in contact with the measured object.

The above structure preferably includes a sixth mechanism. The sixth mechanism preferably has a function of heating the chamber. It is preferred that the chamber be thermally connected to the fifth mechanism.

The above structure preferably includes a seventh mechanism. The seventh mechanism preferably has a function of heating the fifth mechanism.

The above structure preferably includes a measuring instrument. It is preferred that the measuring instrument be electrically connected to the probe and have a function of measuring current flowing in the measured object. In that case, a control device having a function of synchronizing the measuring instrument and the first mechanism to control them is preferably included.

Another embodiment of the present invention is a manufacturing line including the measurement device and a device for manufacturing the measured object.

Another embodiment of the present invention is a measurement system including the measurement device and a computer connected to the measurement device.

Another embodiment of the present invention is a measurement system including the measurement device, a computer connected to the measurement device, and a memory device connected to the computer. The memory device has a function of storing data obtained using the measurement device.

Another embodiment of the present invention is a measurement method including a first step of positioning a measured object on a stage in a chamber with reduced pressure, a second step of making a probe in contact with the measured object, and a third step of sensing an element released from the measured object and measuring current flowing in the measured object using the probe while temperature of the stage is increased.

The measurement method preferably includes a fourth step after the third step. In the fourth step, an element released from the measured object is sensed and current flowing in the measured object is measured using the probe while the temperature of the stage is held at a predetermined temperature.

The measurement method preferably includes a fifth step after the third step. In the fifth step, an element released from the measured object is sensed and current flowing in the measured object is measured using the probe while the temperature of the stage is decreased.

The measurement method preferably includes, before the first step, a sixth step of heating the chamber. In that case, in the sixth step, the chamber is preferably heated at a temperature higher than or equal to 80° C. and lower than or equal to 300° C. for 6 hours or longer.

The measurement method preferably includes, before the first step, a seventh step of heating a probe supporting mechanism In that case, in the seventh step, the probe supporting mechanism is preferably heated at a temperature higher than or equal to 80° C. and lower than or equal to 300° C. for 6 hours or longer.

In the measurement method, the measured object is preferably a powdered object, a pellet-like object, a plate-like object, a spherical object, or a thin film formed over a substrate. Alternatively, the measured object is preferably any of a wiring, a semiconductor element, a resistor, and a capacitor formed over a substrate, or a circuit including at least two thereof.

One embodiment of the present invention can provide a measurement method or a measurement device for identifying a factor of a change in the electrical characteristics of a substance. One embodiment of the present invention can provide a measurement method or a measurement device for determining the temperature dependence of the electrical characteristics of a substance. One embodiment of the present invention can provide a measurement method or a measurement device for measuring a change in the electrical characteristics due to a change in the composition of a substance.

### BRIEF DESCRIPTION OF THE DRAWINGS

FIG. 1 illustrates a structure example of a measurement device of one embodiment.

FIG. 2 illustrates a structure example of a measurement device of one embodiment.

FIGS. 3A to 3F each illustrate a structure example of a probe supporting mechanism of one embodiment.

FIG. 4 is a block diagram illustrating an example of a measurement system of one embodiment.

FIGS. 5A to 5C are flow charts each illustrating an example of a measurement procedure of one embodiment.

FIGS. 6A to 6E each illustrate an example of a measurement method of one embodiment.

FIGS. 7A to 7D each illustrate an example of a measurement method of one embodiment.

FIGS. 8A and 8B each show an example of measured data of one embodiment.

### DETAILED DESCRIPTION OF THE INVENTION

Embodiments will be described in detail with reference to the drawings. Note that the present invention is not limited to the following description, and it will be easily understood by those skilled in the art that various changes and modifications can be made without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. Further, the same hatch pattern is applied to similar functions, and these are not especially denoted by reference numerals in some cases.

Note that in each drawing described in this specification, the size, the layer thickness, or the region of each component is exaggerated for clarity in some cases. Therefore, embodiments of the invention are not limited to such scales.

Note that ordinal numbers such as “first” and “second” in this specification and the like are used in order to avoid confusion among components, and the terms do not limit the components numerically.

### Embodiment

In this embodiment, structure examples of a measurement device and examples of a measurement method of one embodiment of the present invention will be described with reference to drawings.

### [Structure Example of Measurement Device]

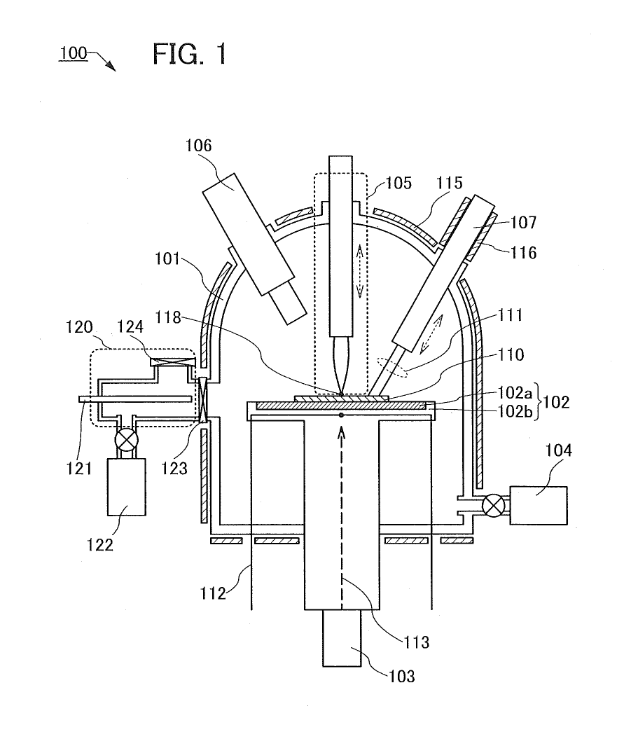

FIG. 1 is a schematic cross-sectional view of a measurement device 100 described in this structure example.

The measurement device 100 illustrated in FIG. 1 includes a chamber 101, a stage 102, a stage heating mechanism 103, a pressure adjusting mechanism 104, a temperature measuring mechanism 105, a gas analyzing mechanism 106, and a probe supporting mechanism 107. A load lock chamber 120 is connected to the chamber 101.

FIG. 1 illustrates the case where a heating mechanism 115 for heating the chamber 101 and a heating mechanism 116 for heating the probe supporting mechanism 107 are provided. The heating mechanisms 115 and 116 may be removable or fixed.

Note that FIG. 1 illustrates a structure example of the measurement device 100, and the measurement device 100 does not necessarily include all the components illustrated in FIG. 1. One embodiment of the invention can be formed by selecting at least one necessary component or extracting and combining at least two necessary components from the components illustrated in FIG. 1. The same applies to other drawings referred to below.

The components will be described below.

### <Chamber>

The chamber 101 has a function of keeping its inside pressure reduced. When a metal with high stiffness such as stainless or an alloy is used for a member of the chamber 101, for example, the hermeticity can be improved. It is preferred to use a material with high heat resistance for the member of the chamber 101. The member of the chamber 101 preferably at least has heat resistance so as not to be deformed by heat of bake treatment described later.

### <Stage and Stage Heating Mechanism>

The stage 102 is provided in the chamber 101 and has a function of holding a sample 110. In FIG. 1, the stage 102 includes a first stage 102a that absorbs infrared light and a second stage 102b that transmits light.

The stage heating mechanism 103 is positioned below the second stage 102b. Described here is the case where a lamp that emits infrared light 113 is used as the stage heating mechanism 103. Note that the second stage 102b is formed using a material that transmits at least part of the infrared light 113.

The infrared light 113 emitted from the stage heating mechanism 103 passes the second stage 102b and reaches the first stage 102a. The first stage 102a is heated when absorbing the infrared light 113. As a result, the sample 110 positioned on the first stage 102a can also be heated.

In the case where a material that absorbs infrared light is used for the sample 110, the first stage 102a is not necessarily provided or a light-transmitting material may be used for the first stage 102a. In that case, the sample 110 can be heated when being irradiated with the infrared light 113 that has passed the stage 102.

In addition, the stage 102 may be provided with a thermocouple 112 as illustrated in FIG. 1. The thermocouple 112 can measure the temperature of the stage 102 (specifically, the first stage 102a or the second stage 102b). Hereinafter, the temperature of a stage measured by the thermocouple 112 is referred to as stage temperature, in some cases.

### <Pressure Adjusting Mechanism>

The pressure adjusting mechanism 104 has a function of reducing the pressure in the chamber 101. As the pressure adjusting mechanism 104, a gas transfer vacuum pump such as a rotary pump, a mechanical booster pump, a diffusion pump, or a turbo molecular pump, or an entrapment vacuum pump such as an ion pump, a getter pump, or a cryopump can be used, for example. Two or more pumps may be used in combination.

As illustrated in FIG. 1, a valve may be provided between the pressure adjusting mechanism 104 and the chamber 101. The pressure adjusting mechanism 104 may include a pressure gauge used for measuring the pressure in the chamber 101. The pressure adjusting mechanism 104 may also include a leak valve or the like used for returning the pressure in the chamber 101 to the atmospheric pressure.

### <Temperature Measuring Mechanism>

The temperature measuring mechanism 105 has a function of measuring the temperature of the sample 110. FIG. 1 illustrates the case where the temperature measuring mechanism 105 includes a thermocouple 118. The temperature measuring mechanism 105 can make the thermocouple 118 in contact with the sample 110 at the time of measurement. The temperature measuring mechanism 105 preferably has a mechanism for moving the thermocouple 118 up or down so that the thermocouple 118 is apart from the sample 110 when the sample 110 is brought in or out.

Note that the structure of the temperature measuring mechanism 105 is hot limited to that including the thermocouple 118 as long as the temperature of the sample 110 can be measured. For example, a structure with which temperature is measured using a radiation thermometer or the like without contact can be employed. In that case, a light-transmitting window portion may be provided on the chamber 101 and the radiation thermometer may be provided outside the chamber 101.

### <Gas Analyzing Mechanism>

The gas analyzing mechanism 106 has a function of sensing an element in the chamber 101. For example, a gas released from the sample 110 being heated can be sensed. It is preferred that a device capable of mass spectrometry, typified by a mass spectrometer such as a quadrupole mass spectrometer, a time-of-flight mass spectrometer (TOF-MS), or a magnetic deflection mass spectrometer, be used as the gas analyzing mechanism 106. A quadrupole mass spectrometer can be reduced in size relatively easily; thus, the measurement device can be simplified. A TOF-MS can measure an element (or a molecule) having an extremely large mass with high sensitivity. A magnetic deflection mass spectrometer allows measurement with extremely high sensitivity.

Note that the gas analyzing mechanism 106 can be, other than the above mass spectrometers, an optical spectrometer using laser or infrared light or a gas adsorption analyzer, for example. In the case of using an optical spectrometer, a light-transmitting window portion may be provided on the chamber 101 and the spectrometer may be provided outside the chamber 101. In particular, when a kind of the measured element is limited and an optical spectrometer suitable for the element is used, the spectrometer is not necessarily provided in the chamber. As a result, an effect of degassing from the spectrometer can be eliminated and measurement can be performed with high accuracy.

### <Probe Supporting Mechanism>

The probe supporting mechanism 107 has functions of supporting a probe 111 and making the probe in contact with the sample 110.

A member of the probe supporting mechanism 107 preferably has at least heat resistance so as not to be deformed by heat of the bake treatment described later. In addition, it is preferred to use, at least for a surface of the probe supporting mechanism 107, a material from which a gas and the like are less likely to be released by heat applied at the time of measurement.

The probe supporting mechanism 107 is preferably thermally connected to the chamber 101 because the probe supporting mechanism 107 can be heated at the same time as the chamber 101 by the bake treatment described later. The probe supporting mechanism 107 and the chamber 101 may be in contact with each other or may be thermally connected to each other with a thermal conductor provided therebetween. For the thermal conductor, a material with high thermal conductivity, such as a metal or an alloy, is preferably used. When a metal, an alloy, or the like is provided between the chamber 101 and the probe supporting mechanism 107, a leakage that occurs when the pressure in the chamber 101 is reduced can be suppressed.

In FIG. 1, the probe supporting mechanism 107 is columnar and two probes 111 are each supported to be parallel to the longitudinal direction of the probe supporting mechanism 107. The probe supporting mechanism 107 illustrated in FIG. 1 can move the probes 111 in the longitudinal direction so that the probes 111 is made in contact or apart from the sample 110.

The structure of the probe 111 can be selected as appropriate depending on the shape of a sample or a method for electrical measurement. Although the case of using two probes is illustrated in FIG. 1, three or more probes may be used. The structure of the probe supporting mechanism 107 can be changed depending on the structure of the probe 111.

When a circuit test element group (TEG) having a plurality of terminals is used as a sample, for example, the number of probes prepared may correspond to the number of the terminals. Alternatively, a probe card described later may be used rather than the probes. In the case where alignment of a probe contact position requires high accuracy, for example, in the case where a terminal with which the probe is in contact is minute, a camera, an optical microscope, or the like for observation of a surface of a sample may be incorporated in the chamber 101 or the probe supporting mechanism 107.

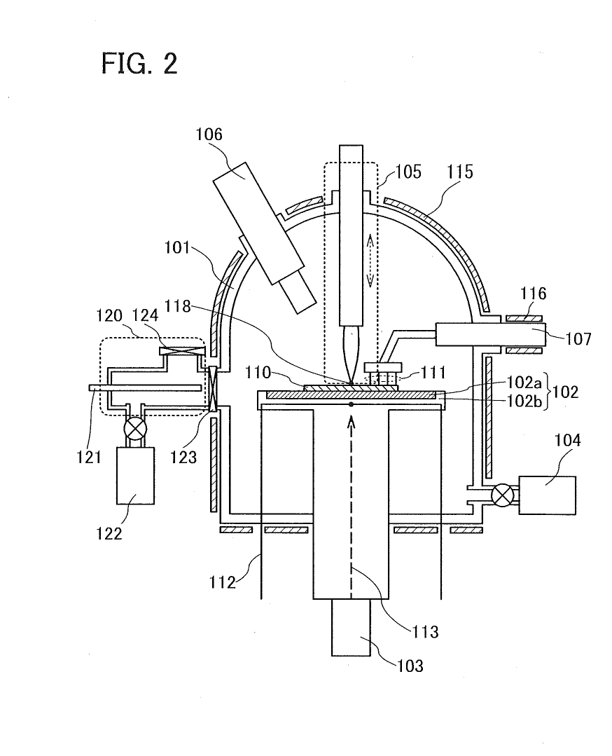

FIG. 2 illustrates the case of using four probes 111. The sheet resistance of the sample 110 can be measured with the four probes by, for example, a four-point probe method. As illustrated in FIG. 2, the probe supporting mechanism 107 may be provided along a direction parallel to the top surface of the stage 102. A plurality of probes fixed to a support (also referred to as a probe card) may be used as the probe 111 as illustrated in FIG. 2.

Next, the specific structure example of the probe supporting mechanism 107 will be described.

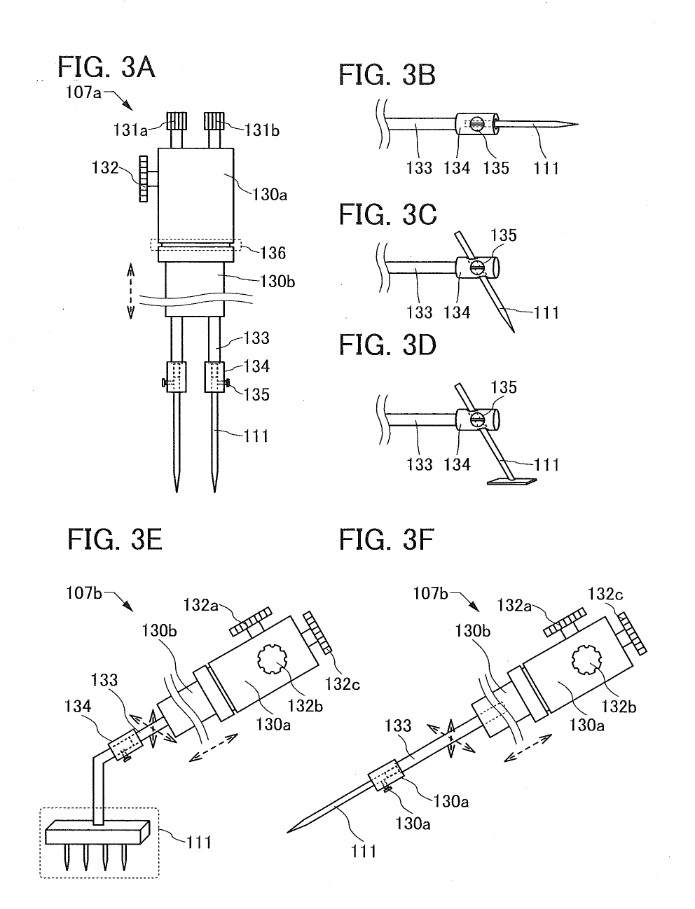

FIG. 3A illustrates a structure example of a probe supporting mechanism 107a that can support two probes 111. The probe supporting mechanism 107a illustrated in FIG. 3A includes a first portion 130a and a second portion 130b. The first portion 130a is provided with adjustment knobs 131a, 131b, and 132. The second portion 130b is provided with two arms 133 and two probe support portions 134. The first portion 130a preferably has a groove portion 136 that joins to an attachment jig for attaching the probe supporting mechanism 107a to the chamber 101.

The second portion 130b is connected to the first portion 130a such that the second portion 130b moves up and down using the adjustment knob 132.

The probe support portion 134 is provided at an end of the arm 133 attached to the second portion 130b. The probe support portion 134 can support the probe 111. In FIG. 3A, the probe 111 is fixed to the probe support portion 134 by a screw 135. Such a removable probe 111 can be easily replaced when being broken, deformed, or worn, for example.

The two arms 133 can be moved independently using the two adjustment knobs 131a and 131b attached to the first portion 130a. Accordingly, the positions where the probes 111 are in contact with the sample 110 can be finely adjusted.

The probe support portion 134 illustrated in FIG. 3B is columnar. The probe 111 can be firmly fixed in a hole of the probe support portion 134 only by one screw 135. Alternatively, as illustrated in FIG. 3C, the probe support portion 134 may have a columnar shape and have a hole on a side surface, and the probe 111 may be fixed so that the longitudinal directions of the probe 111 and the arm 133 form a predetermined angle.

The probe 111 needs not to have a needle-like shape; the probe 111 with a plate-like end may be used as illustrated in FIG. 3D. In the case where a relatively fragile material such as some kinds of porous materials, some kinds of porous ceramic, or a pellet-like material obtained by pressing powder is used for the sample 110, for example, the probe 111 having a shape such that the plane of the probe 111 is in contact with the plane of the sample 110 is used, in which case the sample 110 can be prevented from being broken. Although not illustrated, the probe 111 may have an end with a curved surface, such as a spherical end or an oval end.

Note that the shape of the probe support portion 134 is not limited to the above as long as the probe 111 can be fixed. For example, the probe 111 may be fixed by being sandwiched between two plate-like members or fixed by a plate spring. Still, the above-described structure in which the probe 111 is fixed in a hole of the probe support portion 134 is preferable because the probe 111 does not rotate by the force applied to the end. In the case of using two plate-like members, a plate spring, or the like, the probe support portion 134 preferably includes a groove or a concave portion serving as a guide for fixing the probe 111 so that the probe 111 does not rotate.

A probe supporting mechanism 107b illustrated in FIG. 3E is different from the probe supporting mechanism 107a mainly in the structures of adjustment knobs.

The first portion 130a is provided with adjustment knobs 132a, 132b, and 132c. The adjustment knob 132c has a function of moving the first portion 130a and the second portion 130b up and down relatively, similarly to the adjustment knob 132.

The adjustment knobs 132a and 132b each have a function of moving the arm 133. Specifically, the adjustment knobs 132a and 132b each have a function of moving the arm 133 in a direction perpendicular to the extending direction of the arm 133. It is preferable that the direction in which the arm 133 moves using the adjustment knob 132a and the direction in which the arm 133 moves using the adjustment knob 132b intersect with each other. It is further preferable that the directions intersect with each other at right angles. The adjustment knobs 132a, 132b, and 132c can freely adjust the position of the probe 111 attached to the end of the arm 133 three-dimensionally.

FIG. 3E illustrates an example where a four-point probe card is used as the probe 111. FIG. 3F illustrates the case where one needle-like probe is used as the probe 111. In that case, the chamber 101 is provided with a necessary number of (e.g., two or more) probe supporting mechanisms 107b.

Although the case where the probe supporting mechanism 107 has a structure in which the position of the arm 133, upward/downward movement of the second portion 130b with respect to the first portion 130a, and the like are adjusted using the adjustment knobs is described here, the probe supporting mechanism 107 may include a motor so that the position of the aim 133 can be remotely adjusted. In that case, a controller for operating the motor may be used. Alternatively, a structure in which the probe supporting mechanism 107 is electrically connected to a computer 140 described later so that the position of the arm 133 can be adjusted on the computer 140 is preferred.

The above is the description of the probe supporting mechanism 107.

### <Load Lock Chamber>

The load lock chamber 120 illustrated in FIG. 1 is connected to the chamber 101 by a gate valve 123. Furthermore, a gate valve 124 is provided between the load lock chamber 120 and the air. The load lock chamber 120 includes a transfer mechanism 121 and a pressure adjusting mechanism 122. The structure of the pressure adjusting mechanism 122 can be similar to that of the pressure adjusting mechanism 104.

The sample 110 is transferred into the chamber 101 in the following manner. First, the pressure in the load lock chamber 120 is set to be the atmospheric pressure or higher, the gate valve 124 is opened, and the sample 110 is placed on the transfer mechanism 121. At this time, the gate valve 123 is preferably closed and the pressure in the chamber 101 is preferably reduced. Next, the gate valve 124 is closed, and the pressure in the load lock chamber 120 is reduced to be equivalent to the pressure in the chamber 101 using the pressure adjusting mechanism 122. After that, the gate valve 123 is opened, the sample 110 is placed on the stage 102 by the transfer mechanism 121, and the gate valve 123 is closed. Note that the sample 110 can be transferred from the chamber 101 through the inverse process.

With the load lock chamber 120 connected to the chamber 101, the sample 110 can be transferred in/out without exposing the interior of the chamber 101 to the air, as described above. Accordingly, an inner wall of the chamber 101 and surfaces of other members in the chamber 101 can be kept clean. As a result, degassing therefrom that occurs when the sample 110 is heated for measurement can be suppressed, leading to extremely accurate measurement.

### <Heating Mechanism>

The heating mechanism 115 has a function of heating the chamber 101. A typical example of the heating mechanism 115 is a heater. The heating mechanism 115 may be incorporated in a member of the chamber 101, or may be fixed to the inner wall or an outer wall of the chamber 101. A removable heater (e.g., a rubber heater, a ribbon heater, a seat heater, a mantle heater, or a cord heater) may be provided on the chamber 101 as the heating mechanism 115 only when necessary. Alternatively, a lamp heater or the like may be used as the heating mechanism 115.

The chamber 101 is heated by the heating mechanism 115, whereby impurities adsorbed on the inner wall of the chamber 101 can be detached and the inner wall of the chamber 101 can be cleaned.

It is preferred that, as described above, the chamber 101 be thermally connected to the probe supporting mechanism 107. In that case, heat is conducted to the probe supporting mechanism 107 when the chamber 101 is heated by the heating mechanism 115, so that the probe supporting mechanism 107 can be heated concurrently. As a result, surfaces of the probe supporting mechanism 107 and the probe 111 can also be cleaned.

In addition to the heating mechanism 115, the heating mechanism 116 for heating the probe supporting mechanism 107 is preferably provided. When the probe supporting mechanism 107 is directly heated by the heating mechanism 116, the surfaces of the probe supporting mechanism 107 and the probe 111 can be cleaned more effectively. The temperature of the heating mechanism 115 and the temperature of the heating mechanism 116 can be set at the same temperature or different temperatures.

When both the heating mechanism 115 and the heating mechanism 116 are used, the chamber 101 and the probe supporting mechanism 107 may be thermally isolated from each other. In the case where the heat resistant temperature of a member of the probe supporting mechanism 107 is relatively low, for example, the temperature of the heating mechanism 116 is set to be lower than that of the heating mechanism 115, so that heat from the chamber 101 is not conducted to the probe supporting mechanism 107. In that case, breakage of the probe supporting mechanism 107 due to overheating can be prevented.

The above is the description of the measurement device 100.

### [Sample]

The samples (measured objects) 110 measured by the measurement device 100 can have a wide variety of forms. A thin film formed over a substrate can be given as a typical example of the sample. In that case, to eliminate the effect of degassing from the substrate, a substrate over which a thin film to be measured is not formed is preferably used as a reference.

The sample 110 is not limited to a thin film formed over a substrate and can be a wiring, a semiconductor element typified by a transistor or a diode, a resistor, a capacitor, a light-emitting element, an optical element, or the like made by processing the thin film Alternatively, a circuit including at least two of the above can be used as the sample 110. In the case of using such a wiring, element, or circuit, an electrode which is to be in contact with the probe 111 is preferably provided on a surface thereof.

Other than the above, the sample 110 can be a powdered sample, a pellet-like sample obtained by pressing powder, a plate-like sample, a spherical sample, or the like.

A variety of materials can be used for the sample 110. For example, a material containing an inorganic substance, an organic substance, a metal complex, or the like can be used. A material showing electrical characteristics of a conductor, a metalloid, an insulator, or a semiconductor may be used.

The above is the description of the sample (measured object).

### [Evaluation System]

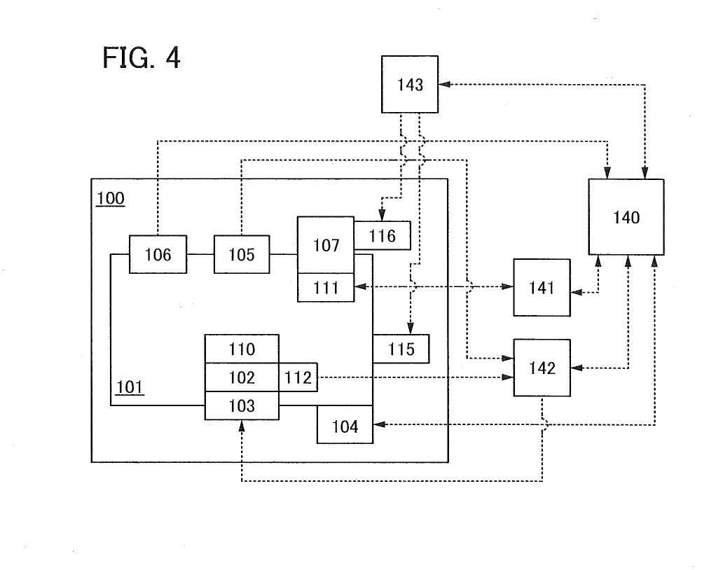

An example of an evaluation system (measurement system) including the measurement device 100 is described below. FIG. 4 is a block diagram illustrating a structure example of the evaluation system. The evaluation system illustrated in FIG. 4 includes, in addition to the measurement device 100, an electrical measuring instrument 141, a first heating mechanism control unit 142, a second heating mechanism control unit 143, the computer (control device) 140, and the like. Dashed arrows between components in FIG. 4 indicate the transfer directions of data or a signal.

The electrical measuring instrument 141 can apply a predetermined potential to the probe 111, and can measure one or both of the current flowing in the probe 111 and the potential of the probe 111. From voltage-current characteristics measured by the electrical measuring instrument 141, the physical properties of the sample 110 typified by electrical resistance or sheet resistance can be estimated, for example. Furthermore, when an electrical element TEG or an electrical circuit TEG is used as the sample 110, the electrical measuring instrument 141 can evaluate the electrical characteristics of the electrical element, the operation of the electrical circuit, or the like. Typical examples of the electrical element are a resistor, a capacitor, a transistor, and a diode.

The electrical measuring instrument 141 can be, for example, a voltage measuring instrument, a current measuring instrument, a power measuring instrument, an oscilloscope, or a measuring instrument specialized for measuring the characteristics of a semiconductor element or a circuit. Alternatively, as the electrical measuring instrument 141, a signal generator and any of the measuring instruments may be used in combination.

Data of the temperature of the sample 110 measured by the temperature measuring mechanism 105 is input to the first heating mechanism control unit 142. Data of stage temperature (specifically, a potential difference) measured by the thermocouple 112 is also input to the first heating mechanism control unit 142. The first heating mechanism control unit 142 can control the operation of the stage heating mechanism 103 on the basis of these temperature data to control the stage temperature or the temperature of the sample 110.

The second heating mechanism control unit 143 can control the temperature of the heating mechanism 115 and the heating mechanism 116.

Data obtained by the gas analyzing mechanism 106 is input to the computer 140. A measurer can analyze the data using the computer 140.

As illustrated in FIG. 4, the electrical measuring instrument 141 and the first heating mechanism control unit 142 are preferably connected to the computer 140 to be controlled on the computer 140. In that case, the electrical measuring instrument 141 and the stage heating mechanism 103 can be controlled in synchronization with each other, and a variety of measurement sequences can be easily performed.

When the second heating mechanism control unit 143 and the pressure adjusting mechanism 104 are also controlled on the computer 140 as illustrated in FIG. 4, a user can unify the operation of the evaluation system on the computer, leading to improvements in operability and convenience. Here, the computer 140 can also be referred to as a control device.

Note that it is preferred to provide a memory device connected to the computer 140. The memory device can store data measured using the measurement device 100. The memory device may be incorporated in the computer 140. Memory devices can be roughly classified into a main memory device and an auxiliary memory device. As the memory device, a storage medium drive such as a hard disk drive (HDD) or a nonvolatile solid state drive (SSD) device can be used, for example.

The above is the description of an example of the evaluation system in which the measurement device 100 is used.

Note that the measurement device 100 is preferably incorporated in a manufacturing line including a device for manufacturing a measured object. When the measurement device 100 is incorporated in a manufacturing line, the measurement device 100 can be used for a sampling inspection in a manufacturing process, for example.

### [Example of Measurement Procedure]

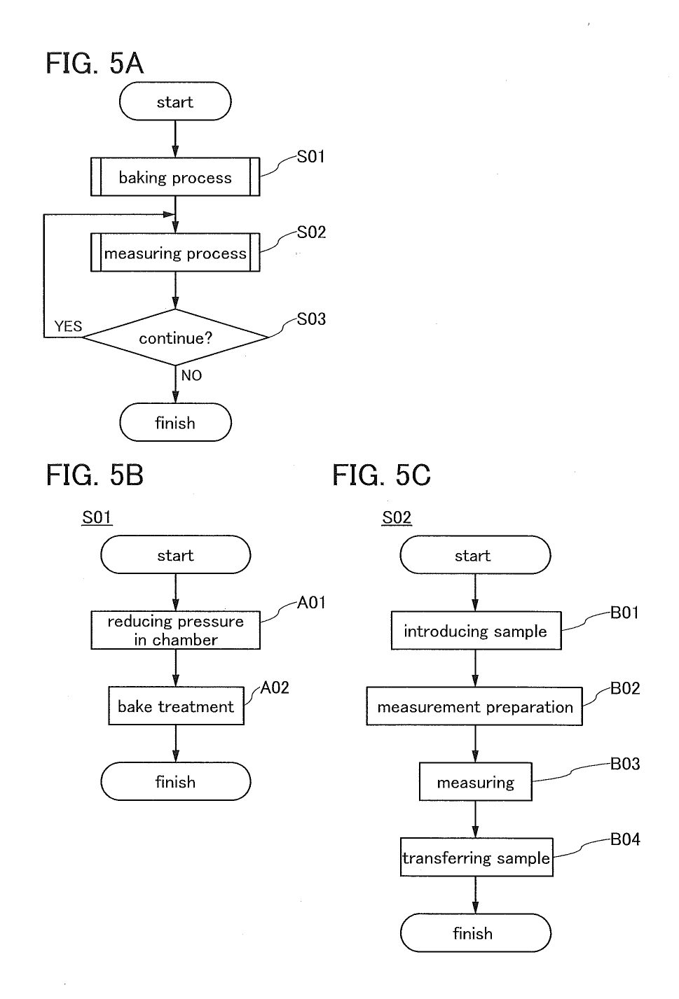

Next, an example of a measurement procedure using the measurement device 100 will be described. FIGS. 5A to 5C are flow charts showing the example of the measurement procedure.

FIG. 5A shows the entire flow of the measurement procedure. A baking process (S01) and a measuring process (S02) are performed in this order. After the measuring process (S02) terminates, the measuring process (S02) is performed again or the measurement terminates depending on whether another sample is measured to continue the measurement (S03).

FIG. 5B and FIG. 5C show a flow of the baking process (S01) and a flow of the measuring process (S02), respectively.

### <Baking Process>

First, the pressure in the chamber 101 is reduced (A01) using the pressure adjusting mechanism 104. Here, the pressure in the chamber is preferably reduced to, for example, lower than or equal to 5×10⁻⁶ Pa, further preferably lower than or equal to 1×10⁻⁶ Pa, still further preferably lower than or equal to 1×10⁻⁷ Pa.

Subsequently, bake treatment is performed (A02) using the heating mechanism 115 to heat the chamber 101. In the case where the chamber 101 and the probe supporting mechanism 107 are thermally connected, the probe supporting mechanism 107 can also be heated at the same time. The probe supporting mechanism 107 is heated at the same time as the chamber 101 also in the case where the heating mechanism 116 is provided.

The chamber 101 and the probe supporting mechanism 107 are heated with the pressure in the chamber 101 reduced, whereby a molecule and the like adsorbed on a surface of the inner wall of the chamber 101, the surface of the probe supporting mechanism 107, and the like can be effectively removed to clean the surfaces. In the case where a material from which a gas is released by heat is used for members of the chamber 101 and the probe supporting mechanism 107, the gas is sufficiently released by the bake treatment at this time; accordingly, a release of the gas by heat generated in the subsequent measuring process can be suppressed and accurate measurement can be thus performed.

The temperature of the bake treatment performed using the heating mechanism 115 and the heating mechanism 116 is preferably as high as possible. However, the temperature is set to be, for example, higher than or equal to 80° C. and lower than or equal to 300° C., preferably higher than or equal to 100° C. and lower than or equal to 200° C., and further preferably higher than or equal to 120° C. and lower than or equal to 150° C., in consideration of heat resistance, safety, and the like of the members of the chamber 101, the probe supporting mechanism 107, and the like. The time for the bake treatment is preferably as long as possible and is, for example, longer than or equal to 6 hours, preferably longer than or equal to 12 hours, further preferably longer than or equal to 24 hours, still further preferably longer than or equal to 48 hours, and yet still further preferably longer than or equal to 72 hours.

The pressure in the chamber 101 might be reduced through the bake treatment. The pressure in the chamber 101 after the bake treatment can be, for example, lower than or equal to 3×10⁻⁷ Pa, preferably lower than or equal to 1×10⁻⁷ Pa, further preferably lower than or equal to 7×10⁻⁸ Pa, still further preferably lower than or equal to 5×10⁻⁸ Pa, and yet still further preferably lower than or equal to 1×10⁻⁸ Pa.

When the pressure in the chamber 101 is kept reduced after the baking process, the inside of the chamber 101 can be kept in excellent condition. Thus, the bake treatment is not necessarily performed every time a sample is exchanged, and one baking process only needs to be performed when the measurement device 100 is started. Note that in the case where plural measurements decrease the cleanliness of the inside of the chamber 101 because a large amount of gas or a gas easily adsorbed on the inner wall of the chamber 101 is released from the sample, for example, the baking process may be performed at the time of exchanging the sample.

In the baking process, the stage 102 may be heated by the stage heating mechanism 103. In that case, the heating temperature is preferably as high as possible; however, the temperature is set as appropriate in consideration of the heat resistance of the stage 102. In the case where silicon carbide is used for the stage 102a and quartz is used for the stage 102b, for example, the heating temperature is set at higher than or equal to 500° C. and lower than or equal to 1200° C., preferably higher than or equal to 800° C. and lower than or equal to 1200° C., and typically at 1000° C. Heating time is set to be shorter than or equal to the time for the baking process and is, for example, longer than or equal to 30 minutes, preferably longer than or equal to 1 hour, and further preferably longer than or equal to 2 hours.

Through the above, the baking process terminates. After the baking process, the measuring process is performed.

### <Measuring Process>

First, the sample 110 is introduced (B01). The sample 110 is introduced through the load lock chamber 120 in the above-described manner.

Next, a preparation for the measurement is made (B02). Specifically, the probe 111 is made in contact with the sample 110 placed on the stage 102 using the probe supporting mechanism 107. In the case of using the thermocouple 118 as the temperature measuring mechanism 105, the thermocouple 118 is then made in contact with a surface of the sample 110.

After the preparation for the measurement is completed, the measurement starts (B03). In the measurement, while the stage temperature or the sample temperature is changed or maintained, a gas released from the sample 110 is sensed by the gas analyzing mechanism 106 and at the same time, current flowing in the sample 110 or the like is measured through the probe 111 while an appropriate potential is applied to the probe 111. A specific example of the measurement sequence will be described later.

In the measurement, for example, at least one of currents flowing in a plurality of the probes 111 may be obtained while a fixed potential is applied to each of the probes 111, or while at least one of potentials applied to the probes 111 is changed.

The measurement may be performed once or plural times when the stage temperature or the sample temperature reaches a predetermined temperature. Plural measurements at a certain temperature can reduce measurement errors to increase the reliability of data.

After the measurement, the sample 110 is transferred out (B04). First, the probe 111, the thermocouple 118, and the like in contact with the sample 110 are made apart from the sample 110. Then, the sample is transferred from the measurement device 100 through the load lock chamber 120 in the above-described manner.

Through the above, the measuring process terminates.

The above is the description of an example of the measurement procedure.

### [Example of Measurement Method]

Specific examples of the measurement method and the measurement sequence will be described below with reference to drawings.

In the measurement, control of the temperature of the sample 110 or the stage, measurement using the gas analyzing mechanism 106, and electrical measurement of the sample 110 using the probe 111 are performed in combination.

In the case of using a mass spectrometer as the gas analyzing mechanism 106, detection intensities of one or more kinds of mass-to-charge ratios (m/z) can be measured. For example, kinds of ions, molecules, and the like (specifically, mass-to-charge ratios) contained in a gas released from the sample 110 and the released amounts of the ions, molecules, and the like can be estimated.

There are a variety of measurements that can be used as the electrical measurement using the probe 111, as described above. Examples of the simplest measurement are voltage-current characteristics measurement by a two-point probe method and sheet resistance measurement by a four-point probe method.

To measure the conductivity of the sample 110, the following methods can be employed, for example. As one method, current that flows when constant voltage is applied to the sample 110 is measured to estimate the resistance. In that case, current may be made to flow in the sample 110 all the time during the measurement period and the sampling of current values is performed periodically, or current may be made to flow in the sample 110 only when sampling is performed. As the other method, the resistance is estimated from the slope of voltage-current characteristics obtained by measuring current with voltage applied to the sample 110 swept.

It is preferred that the sampling timing of the measurement using the gas analyzing mechanism 106 be synchronized with the sampling timing of the electrical measurement using the probe 111. In that case, the frequencies of sampling may be the same, or one frequency of sampling may be a constant multiple of the other.

Here, the frequency of sampling in the measurement using the gas analyzing mechanism 106 is preferably higher than that in the electrical measurement. If electrical characteristics change when a gas is released from the sample 110, for example, the change in the electrical characteristics can be immediately sensed in the electrical measurement without any delay after the gas release. In contrast, the gas released from the sample 110 might be sensed with a delay immediately after the gas is released from the sample 110. The delay might be long particularly when the frequency of sampling in the gas sensing is low; thus, the frequency of the sampling is preferably as high as possible.

It is also preferred that the timing of temperature control using the stage heating mechanism 103, the timing of the measurement using the gas analyzing mechanism 106, and the timing of the electrical measurement using the probe 111 be synchronized with one another. The computer 140 in FIG. 4 can be used to execute a program for synchronizing and controlling the timing, for example. In that case, it is preferred that a measurer can arbitrarily set a variety of parameters for the measurement in advance. Examples of the measurement parameters for controlling the stage heating mechanism are temperature such as starting and end temperature of the measurement, a rate of the temperature increase, a rate of the temperature decrease, and temperature holding time. Examples of the measurement parameters for controlling the gas analyzing mechanism are selection of a mass-to-charge ratio to be obtained, a frequency of sampling, and the timing of start and end of sampling. Examples of the measurement parameters for controlling the electrical measurement are the timing of start and end of sampling, a frequency of sampling, and parameters appropriate for the measurement conditions suitable for an electrical measurement method used or a kind of a sample used, such as a potential applied to the probe and a current or a potential obtained using the probe.

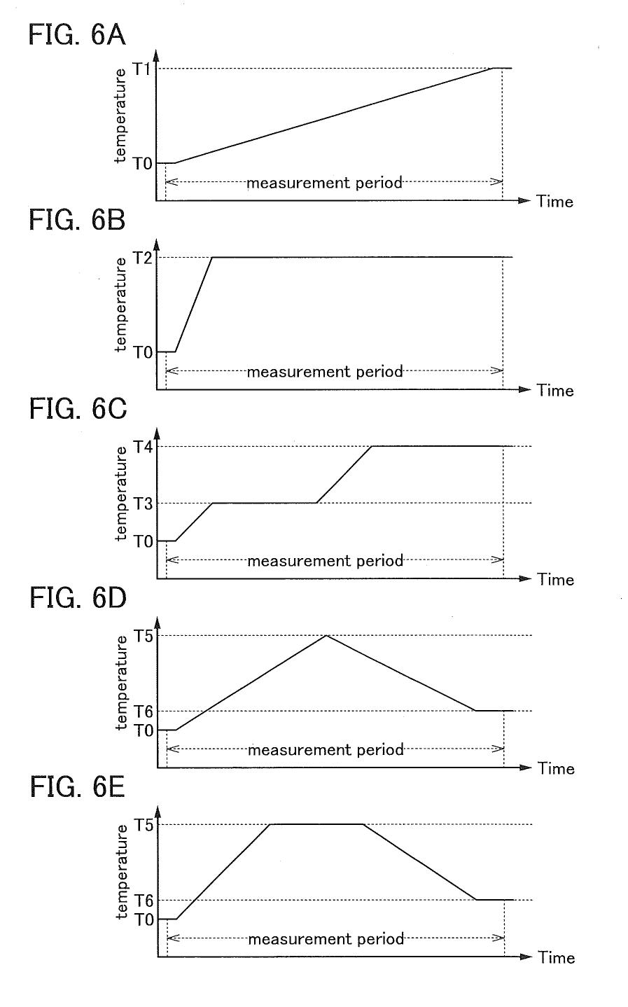

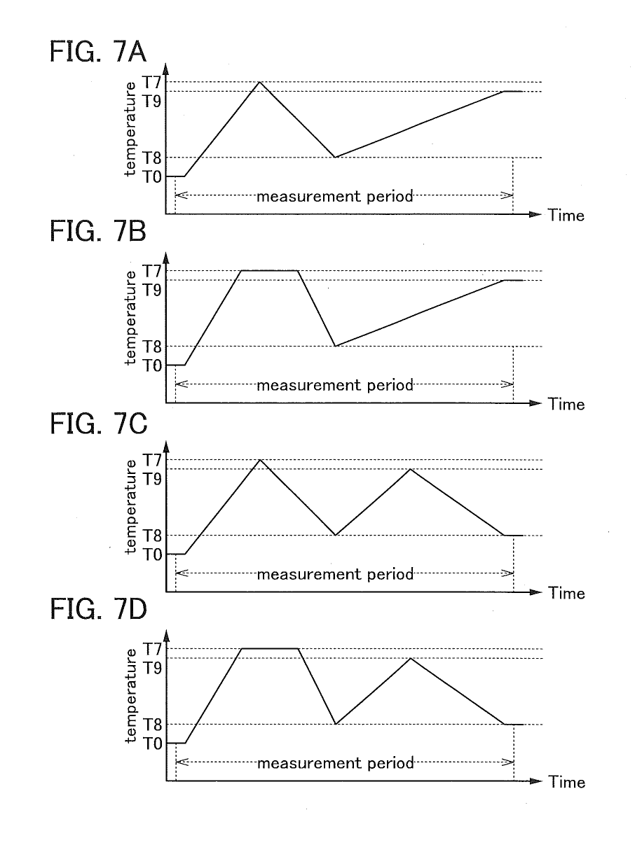

FIGS. 6A to 6E and FIGS. 7A to 7D show examples of the measurement sequence. In each graph, the longitudinal axis represents sample temperature and the lateral axis represents time.

Here, Temperature T0 described below is the temperature at the beginning of the measurement. Temperature T0 can be a given temperature such as room temperature or 0° C. as long as significant degassing from the sample 110 does not occur.

FIG. 6A shows an example of measurement in which the sample temperature is increased from Temperature T0 to Temperature T1 with a constant gradient (rate). An element or a molecule released from the sample 110 usually has a profile with a peak at a specific temperature. Thus, with such measurement, it can be easily specified which element is a factor of a change in electrical characteristics from the correlation between the profile and the change in the electrical characteristics.

FIG. 6B shows an example of measurement in which the sample temperature is increased from Temperature T0 to Temperature T2 and then is kept at Temperature T2. When it is obvious which element is the factor of a change in the electrical characteristics of the sample 110, for example, the released amount of the element and the electrical characteristics are measured at the same time while the temperature is kept at which the element is likely to release, so that the correlation between the released amount of the element and the amount of change in the electrical characteristics can be examined in detail. As shown in FIG. 6C, the sample may be kept at two or more temperatures (Temperature T3 and Temperature T4 in FIG. 6C).

FIG. 6D shows an example of measurement in which the sample temperature is increased from Temperature T0 to Temperature T5 at a constant rate and then is decreased to Temperature T6, which is lower than Temperature T5. With such measurement, the temperature dependence of the electrical characteristics of the sample 110 after an element is released can be measured. When the sample is kept at Temperature T5 as shown in FIG. 6E, the element can be sufficiently released from the sample 110.

FIG. 7A shows an example of measurement in which the sample temperature is increased from Temperature T0 to Temperature T7 at a constant rate, is decreased to Temperature T8, which is lower than Temperature T7, and is then increased to Temperature T9. With such measurement, the electrical characteristics can be compared between the first temperature increase and the second temperature increase; during the first temperature increase, the temperature dependence of the electrical characteristics which might be affected by the release of an element from the sample 110 is measured, whereas during the second temperature increase, the temperature dependence of the electrical characteristics after the element is released (i.e., almost without the effect of the element release) can be measured. As shown in FIG. 7B, the sample may be kept at Temperature T7 after the first temperature increase. Temperature T9 achieved by the second temperature increase is preferably lower than or equal to Temperature T7 achieved by the first temperature increase.

As shown in FIGS. 7C and 7D, the sample temperature may be decreased after the second temperature increase. Although FIGS. 7C and 7D each show the case where the sample temperature is increased and decreased twice, the sample temperature may be increased and decreased three or more times.

The above is the description of the measurement method.

### [Example of Measured Data]

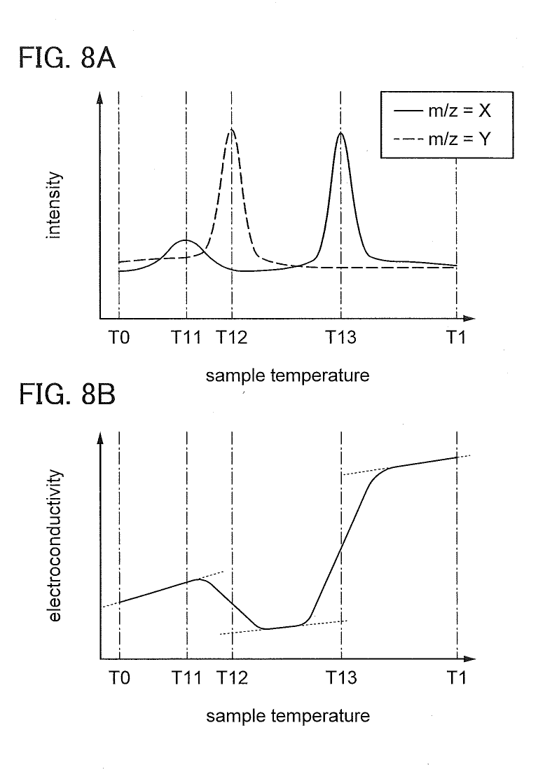

FIGS. 8A and 8B schematically show examples of data obtained by measurement using the measurement sequence in FIG. 6A described as an example. FIG. 8A is a graph on which detection intensities of mass-to-charge ratios X and Y measured using the gas analyzing mechanism 106 are plotted with respect to the sample temperature. FIG. 8B is a graph on which the conductivity of the sample measured using the electrical measuring instrument 141 through the probe 111 is plotted with respect to the sample temperature.

Here, the detection intensity of the mass-to-charge ratio X has peaks at Temperature T11 and Temperature T13, and the detection intensity of the mass-to-charge ratio Y has a peak at Temperature T12 as shown in FIG. 8A.

Furthermore, the conductivity decreases at around Temperature T12 and the conductivity increases at around Temperature T13 as shown in FIG. 8B.

These two results show that, for example, a decrease in the conductivity at around Temperature T12 is probably due to a release of an element corresponding to the mass-to-charge ratio Y from the sample, and an increase in the conductivity at around Temperature T13 is probably due to a release of an element corresponding to the mass-to-charge ratio X from the sample. In addition, since the peak of the detection intensity of the mass-to-charge ratio X at Temperature T11 does not affect the conductivity, the peak of an ion with the mass-to-charge ratio X at Temperature T11 is probably due to, for example, a release of an element adsorbed on the surface of the sample rather than the inside of the sample.

Moreover, when the slope of a curve at temperatures lower than Temperature T12, the slope of a curve between Temperature T12 and Temperature T13, and the slope of a curve at temperatures higher than Temperature T13 are different from one another as shown in FIG. 8B, it can be examined that, for example, conduction mechanisms in the respective temperature ranges are different from one another because the composition and structure of the sample are changed by the release of the elements.

With the use of the measurement device and the measurement method of one embodiment of the present invention as described above, a change in electrical characteristics due to a release of an element from a sample can be examined in more detail.

Such an examination has been very difficult to achieve using a conventional device. A gas released from a sample can be measured by thermal desorption spectroscopy (TDS), and electrical measurement can be performed on the sample before and after the TDS analysis, that is, the sample before and after the release of the gas, for example. However, it is difficult to determine whether the change in the electrical characteristics of the sample before and after the release of the gas is due to a release of an element, and if so, is due to what kind of element, or is caused by another factor such as a change in the crystal morphology of the sample caused by heat. It is also difficult to examine the relationship between a change in the amount of the element released from the sample and the amount of change in the electrical characteristics accurately.

In addition, the measurement device and the measurement method of one embodiment of the present invention allow measurement of the electrical characteristics of a sample in a very clean chamber under reduced pressure. Thus, impurities such as an ion that affect the electrical characteristics of the sample can be prevented from being adsorbed on a surface of the sample during the measurement. For this reason, the reliability of data obtained by the measurement can be improved.

The measurement device and the measurement method of one embodiment of the present invention are expected to produce new insights into physical properties, a physical phenomenon, a conduction mechanism, and the like which are previously unknown, leading to a great development of science and technology.

This application is based on Japanese Patent Application serial no. 2014-081997 filed with Japan Patent Office on Apr. 11, 2014, the entire contents of which are hereby incorporated by reference.

What is claimed is:

1. A measurement device comprising:
a chamber;
a stage;
a first mechanism;
a second mechanism;
a third mechanism;
a fourth mechanism; and
a fifth mechanism,
wherein the stage in the chamber has a function of holding a measured object,
wherein the first mechanism has a function of heating the stage,
wherein the second mechanism has a function of reducing pressure in the chamber,
wherein the third mechanism has a function of measuring temperature of the measured object,
wherein the fourth mechanism has a function of sensing an element in the chamber, and
wherein the fifth mechanism is configured to support a probe and make the probe to be in contact with the measured object.

2. The measurement device according to claim 1 further comprising:
a sixth mechanism,
wherein the sixth mechanism has a function of heating the chamber, and
wherein the chamber is thermally connected to the fifth mechanism.

3. The measurement device according to claim 1 further comprising a seventh mechanism having a function of heating the fifth mechanism.

4. The measurement device according to claim 1 further comprising a measuring instrument electrically connected to the probe, the measuring instrument having a function of measuring current flowing in the measured object.

5. The measurement device according to claim 4 further comprising a control device having a function of synchronizing the measuring instrument and the first mechanism to control them.

6. A manufacturing line comprising:
the measurement device according to claim 1; and
a device for manufacturing the measured object.

7. A measurement system comprising:
the measurement device according to claim 1; and
a computer connected to the measurement device.

8. A measurement system comprising:
the measurement device according to claim 1;
a computer connected to the measurement device; and
a memory device connected to the computer,
wherein the memory device has a function of storing data obtained using the measurement device.

9. A measurement method comprising:
a first step of positioning a measured object on a stage in a chamber with reduced pressure;
a second step of making a probe in contact with the measured object; and
a third step of sensing an element released from the measured object and measuring current flowing in the measured object using the probe while the temperature of the stage is increased.

10. The measurement method according to claim 9 further comprising a fourth step after the third step,
wherein an element released from the measured object is sensed and current flowing in the measured object is measured using the probe while the temperature of the stage is held at a predetermined temperature in the fourth step.

11. The measurement method according to claim 9 further comprising a fifth step after the third step,
wherein an element released from the measured object is sensed and current flowing in the measured object is measured using the probe while the temperature of the stage is decreased in the fifth step.

12. The measurement method according to claim 9 further comprising a sixth step of heating the chamber before the first step.

13. The measurement method according to claim 12, wherein the chamber is heated at a temperature higher than or equal to 80° C. and lower than or equal to 300° C. for 6 hours or longer in the sixth step.

14. The measurement method according to claim 9 further comprising a seventh step of heating a probe supporting mechanism before the first step.

15. The measurement method according to claim 14, wherein the probe supporting mechanism is heated at a temperature higher than or equal to 80° C. and lower than or equal to 300° C. for 6 hours or longer in the seventh step.

16. The measurement method according to claim 9, wherein the measured object is a powdered object, a pellet-like object; a plate-like object, a spherical object, or a thin film over a substrate.

17. The measurement method according to claim 9, wherein the measured object is any of a wiring, a semiconductor element, a resistor, and a capacitor formed over a substrate, or a circuit including at least two thereof.
